(19) United States
(12) Patent Application Publication
(10) Pub. No.: US 2026/0334086 A1
(43) Pub. Date: Oct. 22, 2026

(54) SYSTEMS AND METHODS FOR LAYER FORMATION

(71) Applicant: Samsung Electronics Co., Ltd., Suwon-si (KR)

(72) Inventors: Roman CHEPULSKYY, Santa Clara, CA (US); Dmytro APALKOV, San Jose, CA (US); Jaewoo JEONG, Los Altos, CA (US); FNU IKHTIAR, San Jose, CA (US)

(21) Appl. No.: 19/361,386

(22) Filed: Oct. 17, 2025

Related U.S. Application Data
(60) Provisional application No. 63/790,437, filed on Apr. 17, 2025.

(51) Int. Cl. H10N 50/01; G11C 11/16; H10N 50/10; H10N 50/85

(52) U.S. Cl. CPC H10N 50/01; G11C 11/161; H10N 50/10; H10N 50/85

(57) ABSTRACT

A method for depositing a layer on a substrate is disclosed. The method may include forming a first layer on a substrate, where the first layer may include a surfactant and a first material having a higher surface energy than the substrate, and the forming of the first layer on the substrate may include applying the first material and the surfactant on the substrate, annealing the first layer to segregate the surfactant from the first material of the first layer, and removing the surfactant from the first layer.

### CROSS-REFERENCE TO RELATED APPLICATION

The present application claims priority to and the benefit under 35 U.S.C. § 119(e) of U.S. Provisional Application No. 63/790,437, filed on Apr. 17, 2025, entitled “IMPROVEMENT OF SURFACE MORPHOLOGY FOR MRAM CELL BY SURFACTANT AND SELECTIVE TEMPERATURE ANNEALING,” the entire disclosure of which is incorporated by reference herein.

### BACKGROUND

### 1. Field

Aspects of one or more embodiments relate to systems and methods for layer formation. For example, aspects of one or more embodiments of the present disclosure relate to improvements to layer formation (e.g., surface morphology) in magnetoresistive random-access memory random-access memory (MRAM) devices.

### 2. Description of the Related Art

Layer formation in the manufacturing process of semiconductor devices may include multiple depositing steps, e.g., depositing thin films of conductive, insulating, and/or semiconductor materials onto a substrate respectively, to form a layered structure to achieve desired electrical characteristics of a final semiconductor device, for example, a magnetoresistive random-access memory (MRAM) device. However, depositing different layers with different surface energies on a substrate may be challenging and further impact the performance and reliability of the semiconductor devices.

The above information disclosed in this Background section is only for enhancement of understanding of the background and therefore the information discussed in this Background section does not necessarily constitute prior art.

### SUMMARY

One or more aspects of the present disclosure provide a method for depositing a layer on a substrate that may relatively improve a smooth surface layer on the substrate and relatively improve electrical or magnetic characteristics of magnetoresistive random access memory (MRAM) cell produced utilizing the method, thereby further enhancing electrical or magnetic characteristics of device (e.g., a semiconductor) applying the MRAM cell.

One or more aspects of the present disclosure also provide an apparatus for depositing a layer on a substrate that improves a smooth surface layer on the substrate and improves electrical or magnetic characteristics of MRAM cell produced via the apparatus, thereby further enhancing electrical or magnetic characteristics of electronic device applying the MRAM cell.

One or more aspects of the present disclosure also provide a system for depositing a layer on a substrate that improves a smooth surface layer on the substrate and improves electrical or magnetic characteristics of MRAM cell produced via the system, thereby further enhancing electrical or magnetic characteristics of electronic device applying the MRAM cell.

Additional aspects will be set forth in part in the description which follows and, in part, will be apparent from the description, or may be learned by practice of the presented embodiments of the disclosure.

According to one or more embodiments of the present disclosure, a method may include forming a first layer on a substrate, the first layer including a surfactant and a first material having a higher surface energy than the substrate, where the forming of the first layer on the substrate may include applying the first material and the surfactant on the substrate, annealing the first layer to segregate the surfactant from the first material of the first layer, and removing the surfactant from the first layer.

In one or more embodiments, the first material may have a higher surface energy than the surfactant.

In one or more embodiments, the forming of the first layer on the substrate may include applying the first material and the surfactant on the substrate at a temperature from about 150 °C to about 400 °C.

In one or more embodiments, the first material may include at least one of Fe, FeB, CoFeB, Mn₃Ge, or MnAlGe.

In one or more embodiments, the surfactant may include at least one of F, He, Ne, Ar, Kr, Xe, Na, K, Rb, Ba, Br, Bi, Te, Se, Pb, Tl, Li, Sr, As, Y, Ca, or Sb.

In one or more embodiments, the substrate may include at least one of MgO, SrO, BaO, CaO, or Mg—Al—Oₓ.

In one or more embodiments, the annealing of the first layer may be performed for a period of time from about 50 seconds to about 3 hours at a temperature from about 150 °C to about 400 °C.

In one or more embodiments, the surfactant may be removed from the first layer via a plasma treatment at a temperature from about 250 °C to about 400 °C.

In one or more embodiments, the surfactant may be removed from the first layer via at least one process selected from among an oxidation, a nitridation, and a formation of a surfactant-element X compound.

In one or more embodiments, the method may further include forming a second layer on the first layer, wherein the second layer comprises a second material having a lower surface energy than the first material.

According to one or more embodiments of the present disclosure, an apparatus may include a deposition device to form a first layer on a substrate, the first layer including a surfactant and a first material having a higher surface energy than the substrate, where the forming of the first layer on the substrate may include applying the first material and the surfactant on the substrate, an annealing device to anneal the first layer to segregate the surfactant from the first material of the first layer, and an extraction device to remove the surfactant from the first layer.

In one or more embodiments, the first material may have a higher surface energy than the surfactant.

In one or more embodiments, the deposition device may be further configured to apply the first material and the surfactant on the substrate at a temperature from about 150 °C to about 400 °C.

In one or more embodiments, the first material may include at least one of Fe, FeB, CoFeB, Mn₃Ge, or MnAlGe.

In one or more embodiments, the surfactant may include at least one of F, He, Ne, Ar, Kr, Xe, Na, K, Rb, Ba, Br, Bi, Te, Se, Pb, Tl, Li, Sr, As, Y, Ca, or Sb.

According to one or more embodiments of the present disclosure, a system may include one or more processors configured to form a first layer on a substrate, the first layer including a surfactant and a first material having a higher surface energy than the substrate, anneal the first layer to segregate the surfactant from the first material of the first layer, and remove the surfactant from the first layer.

In one or more embodiments, the forming of the first layer on the substrate may include applying the first material and the surfactant on the substrate.

In one or more embodiments, the forming of the first layer on the substrate may include applying the first material and the surfactant on the substrate at a temperature from about 150 °C to about 400 °C.

In one or more embodiments, the first material may include at least one of Fe, FeB, CoFeB, Mn₃Ge, or MnAlGe.

In one or more embodiments, the surfactant may include at least one of F, He, Ne, Ar, Kr, Xe, Na, K, Rb, Ba, Br, Bi, Te, Se, Pb, Tl, Li, Sr, As, Y, Ca, or Sb.

According to one or more embodiments of the present disclosure, the method provides a method for depositing a layer on a substrate that improves a smooth surface layer on the substrate to the electrical or magnetic characteristics of MRAM cell utilizing the method. For example, the deposition of material having higher surface energy than the substrate may form a smooth, uniform layer on the substrate, thereby improving surface morphology of MRAM cells in thin-film deposition processes and the performance and/or reliability of the MRAM devices.

### BRIEF DESCRIPTION OF THE DRAWINGS

The above and other aspects of the present disclosure will be more clearly understood from the following detailed description of the illustrative, non-limiting embodiments with reference to the accompanying drawings.

FIG. 1A is a diagram illustrating a deposition process with a substrate having high surface energy and deposition material having low surface energy, according to one or more embodiments.

FIG. 1B is a diagram illustrating a deposition process with a substrate having low surface energy and deposition material having high surface energy, according to one or more embodiments.

FIG. 2 is a diagram depicting example elements X for deposition material of Fe₃X and their corresponding surface energy in response to a substrate of MgO, according to one or more embodiments.

FIG. 3 is a diagram depicting example elements and their corresponding surface energy, according to one or more embodiments.

FIG. 4 is a diagram depicting an example preparation process for deposition materials, according to one or more embodiments.

FIG. 5 is a diagram depicting an example method for depositing a layer on a substrate, according to one or more embodiments.

FIG. 6 is a diagram depicting an example extraction step, according to one or more embodiments.

FIG. 7 is a diagram depicting example method for depositing multiple layers on a substrate, according to one or more embodiments.

FIG. 8A is a diagram depicting an example MRAM cell, according to one or more embodiments.

FIG. 8B is a diagram depicting another example MRAM cell, according to one or more embodiments.

FIG. 8C is a diagram depicting yet another example MRAM cell, according to one or more embodiments.

FIG. 9 is a diagram depicting an example Spin-Orbit Torque (SOT) MRAM cell, according to one or more embodiments.

FIG. 10 is a flowchart depicting a method for depositing a layer on a substrate, according to some embodiments of the present disclosure.

FIG. 11 is a block diagram of a system including a MRAM, according to one or more embodiments of the present disclosure.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the terms “or” and “and/or” include any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

The electronic or electric devices and/or any other relevant devices or components according to embodiments of the present disclosure described herein may be implemented utilizing any suitable hardware, firmware (e.g., an application-specific integrated circuit (ASIC)), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Magnetoresistive random-access memory (MRAM) devices store information utilizing magnetic materials as an information recording medium. In terms of manufacturing MRAM cells, depositing a layer on a substrate with different surface energies may be challenging. For example, if (e.g., when) the substrate has a relatively lower surface energy and the material for depositing has relatively higher surface energy, the deposition material would tend to be aggregated and form an uneven layer on the substrate, thereby impacting the performance and reliability of the MRAM devices.

In the deposition process of manufacturing a semiconductor device (e.g., a magnetoresistive random access memory (MRAM)), an optical component, and/or an electronic device, there are several difficulties to deposit a smooth layer on a substrate and/or another layer. For example, if the substrate or a bottom layer that is to be deposited with a deposition layer thereon has lower surface energy than the deposition layer, the material/component of the deposition layer may tend to be aggregated (e.g., form an island) on the surface of the substrate or the bottom layer. Such aggregation on the substrate or the bottom layer may create voids, holes, and/or gaps in the layer, thereby degrading the quality, performance, and reliability of the layers (e.g., thin films or coatings) in the final device. Therefore, one or more aspects of the present disclosure may provide a method for forming a layer. The method may include adding a surfactant to the material of the deposition layer to lower the surface energy of the deposition layer or at least decrease/reduce the difference between the surface energy of the deposition layer and the surface energy of the substrate, thereby improving the smoothness of the deposition layer and the surface morphology of layers in the final device (e.g., a free layer of a MRAM cell).

Thus, aspects of embodiments according to the present disclosure are directed to a system and method that may enable a relatively smooth surface layer on a substrate and relatively improved electrical or magnetic characteristics of the MRAM cell.

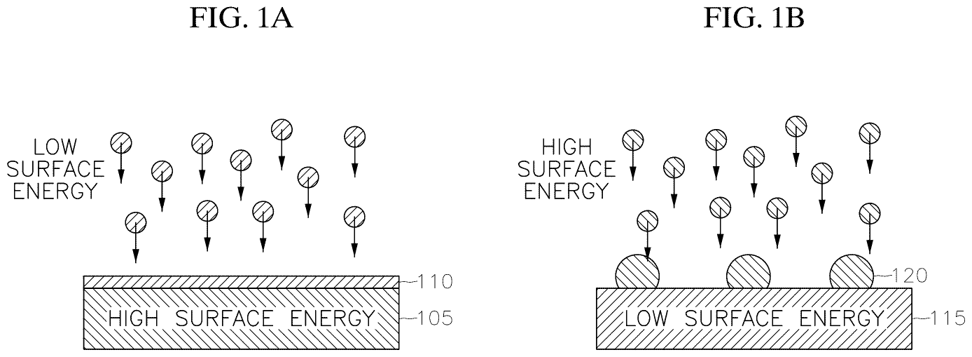

FIG. 1A is a diagram illustrating a deposition process with a substrate having high surface energy and deposition material having low surface energy, according to one or more embodiments. FIG. 1B is a diagram illustrating a deposition process with a substrate having low surface energy and deposition material having high surface energy, according to one or more embodiments.

Referring to FIG. 1A, a layer 110 may be deposited on a substrate 105 in a thin-film deposition process, such as Physical Vapor Deposition (PVD) and/or Chemical Vapor Deposition (CVD). If the substrate 105 has higher surface energy and the material of the layer 110 has lower surface energy, the layer 110 may be relatively smooth and uniform on the substrate 105. Thus, in one or more embodiments, the substrate 105 may have higher surface energy than the material of the layer 110. The deposition process shown in FIG. 1A may have better performance of wetting and render a more even, flat, and uniform surface of the deposition layer (e.g., enhanced 2D material growth), which may be beneficial for reducing surface roughness of the deposition layer in manufacturing the MRAM cells.

Referring to FIG. 1B, a layer 120 may be deposited on a substrate 115 in the thin-film deposition process. If the substrate 115 has lower surface energy and the material of the layer 120 has higher surface energy, the layer 120 may be relatively uneven on the substrate 115, as in the material of the layer 120 may be aggregated on the substrate 115 during the deposition process. Such aggregation on the substrate may render voids, holes, and/or gaps in the deposition layer (e.g., the layer 120), thereby damaging the quality, performance, and reliability of the layers (e.g., the layer 120) in a final product. In one or more embodiments, the substrate 105 may have lower surface energy than the material of the layer 110. In one or more embodiments, the material of the layer 120 may include a material having high surface energy (e.g., CoFeB having a surface energy of 2.5 J/m², Co having surface energy of 2.54 J/m², and/or Ir having a surface energy of 3.02 J/m²), and the substrate 115 may include a low surface energy material (e.g., MgO having a surface energy of 0.96 J/m²). In one or more embodiments, the material(s) for depositing the layer 120 may be utilized to form multiple layers on the substrate 115. Because of the characteristics (e.g., surface energies) of the material for deposition and the substrate, the deposition process shown in FIG. 1B may have less desirable wetting results (e.g., rough surface) and render aggregations on the substrate (e.g., a 3D material growth/formation of island), compared to other devices and manufacturing processes, which may not be beneficial for manufacturing the MRAM cells.

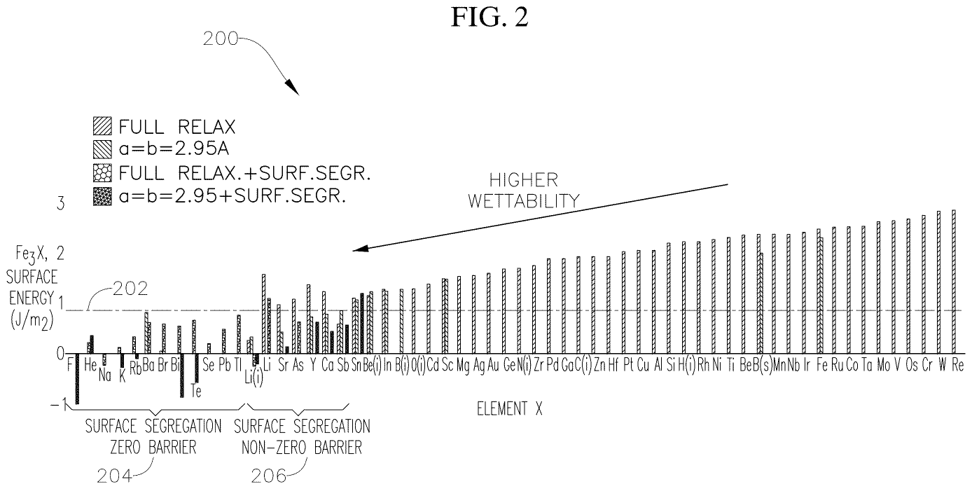

FIG. 2 is a diagram depicting example elements and their corresponding surface energy, according to one or more embodiments.

Referring to FIG. 2, surface energies of multiple elements are each tested with Fe to determine the capability of being a surfactant for depositing a Fe-based layer on a substrate, e.g., a MgO-based substrate. For example, a surfactant is a chemical compound that decreases the surface tension or interfacial tension between two different materials (e.g., between two liquids, between a liquid and a gas, or between a liquid and a solid). In the manufacturing process of the MRAM cells, a surfactant may be a chemical layer/component utilized during manufacturing process to improve the quality of the substrate and/or the tunneling barrier, e.g., an ultra-thin magnesium oxide (MgO) tunnel barrier. The surfactant may be beneficial to generate a more uniform and robust layer/barrier to a cell. Therefore, preparing surfactants by utilizing Fe with different elements in a dilute form (e.g., fewer Fe in dilute solution) may be able to determine which elements are more suitable to be utilized as a surfactant for forming a Fe-based layer on a substrate, e.g., decreasing the surface energy of materials that is used for the Fe-based layer. Higher concentration of Fe in the solution may cause immiscibility. In one or more embodiments, some of these elements may form films exhibiting surface segregation if mixed with Fe and processed (e.g., annealing). For example, a first group of elements 204 may include F, He, Na, K, Rb, Ba, Br, Bi, Te, Se, Pb, and Tl. The surfactants prepared with the first group of elements 204 may show surface segregation with zero barrier if being mixed with Fe. A second group of elements 206 may include Li, Sr, As, Y, Ca, and Sb. The surfactants prepared with the second group of elements 206 may show surface segregation with non-zero barrier if being mixed with Fe.

As shown in FIG. 2, in one or more embodiments, the substrate utilized to test the surface energies of different surfactants may include MgO and/or any other suitable compounds that may function as a surfactant for the deposition material. For example, in FIG. 2, Element X may be utilized as a surfactant (e.g., Surfactant X) to indicate the effect of the element X on the surface energy of Fe. In one or more embodiments, in FIG. 2, bulk crystal structures may be considered irrelevant of substrate. Suitable elements to be utilized/tested in the surfactant may include at least one selected from among F, He, Na, K, Rb, Ba, Br, Bi, Te, Se, Pb, Tl, Li (i), Li, Sr, As, Y, Ca, and Sb. In one or more embodiments, suitable elements to be used in the surfactant may further include at least one selected from among He, Ne, Ar, Kr, and Xe. Theses suitable elements may lower surface energies of the materials for deposition which may improve the wettability in the deposition process. In one or more embodiments, these suitable elements utilized in the surfactant may lower the surface energy by more than about 48% than the surface energy utilizing Fe. For example, surface energy 202 of the MgO-based substrate may be approximately 0.95 J/m², which may be relatively lower than surface energy of Fe 208 (e.g., the surface energy of Fe may be approximately 2.3 J/m²). The elements that may have surface energy lower than Fe may be diluted to lower their surface energies. For example, by dilutions of F, He, Na, K, Rb, Ba, Br, Bi, Te, Se, Pb, Tl, Li (i), Li, Sr, As, Y, Ca, and Sb, the surface energy of each element may be decreased by approximately more than 48% from the surface energy of the original Fe (e.g., the pure Fe or Fe before dilution).

In one or more embodiments, in the deposition process, it may show surface segregation being mixed with Fe. In one or more embodiment, these suitable elements may be utilized at heated deposition.

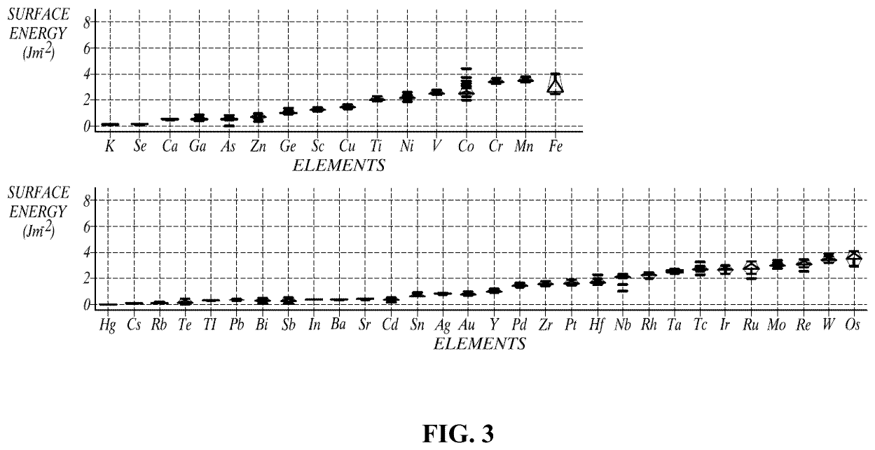

FIG. 3 is a diagram depicting example elements and their corresponding surface energy, according to one or more embodiments.

Referring to FIG. 3, selected elements may be tested for their surface energy. Some of the selected elements (e.g., Li, Na, K, Ca, As, Rb, Sr, Y, Sb, Te, Ba, Tl, Pb, and/or Bi) may demonstrate low surface energy both immiscible in bulk and by Fe dilution (e.g., a set concentration of Fe in the solution). In one or more embodiments, elements selected from among He, Ne, Ar, Kr, and Xe may demonstrate low surface energy both immiscible in bulk and by Fe dilution. In one or more embodiments, surface energy may be determined by the energy penalty of breaking bonds at surface (e.g., the bonds between the substrate and the deposited layer). For example, stronger bonding may indicate higher surface energy. Furthermore, the strength of bonding (e.g., the surface energy) may correlate with the valency, cohesive energy, and/or melting temperature of these elements in the Fe dilution. In one or more embodiments, the elements having lower strength of bonding (e.g., lowest values associated with lower surface energies) may be more suitable than the elements having higher strength of bonding (e.g., higher values associated with higher surface energies). For example, the elements having lower surface energy may be utilized as a surfactant, and these element may have one or more of the following characteristics: (1) having surface energy that may be approximately more than 48% lower the surface energy of Fe; (2) having a feature that may be immiscible with Fe in bulk; and/or (3) having a feature showing surface segregation if (e.g., when) being mixed with Fe. Considering the above characteristics, it may assume that the elements at the edges of Periodic Table may be more suitable because the elements at the edges are far from Fe in Periodic Table, so that these elements may be immiscible with Fe in general and have low cohesive energy which may correlate with low surface energy.

Therefore, the results of surface energies for each element may correspond to the periodic behavior. Although FIG. 3 illustrates various examples of Fe-based surfactants with different elements (e.g., He, Ne, Ar, Kr, and/or Xe) that may lower the surface energy to improve the deposition process, embodiments according to the present disclosure are not limited thereto, and according to various embodiments, the surfactant may include an additional element or be based on a different element that may achieve substantially the same or similar effect.

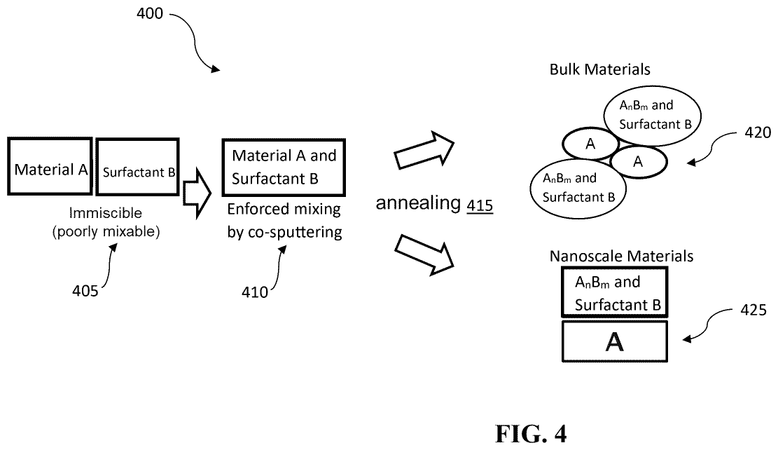

FIG. 4 is a diagram depicting an example preparation process for deposition materials, according to one or more embodiments. Although FIG. 4 illustrates various operations in a preparation process for deposition materials, embodiments according to the present disclosure are not limited thereto, and according to various embodiments, the process may include additional operations, or fewer operations, or the order of operations may vary, unless otherwise stated or implied, without departing from the spirit and scope of embodiments according to the present disclosure.

Referring to FIG. 4, a preparation process 400 may include an immiscible-mixing step (e.g., operation or task) 405, an enforced-mixing step (e.g., operation or task) 410, and an annealing step 415. At the immiscible-mixing step 405, material A and surfactant B may be two immiscible materials. For example, the material A and the surfactant B are immiscible, which may imply that the material A and the surfactant B may be immiscibly/poorly mixed (e.g., not forming a homogeneous mixture of A and B). At the enforced-mixing step 410, the material A and the surfactant B may be forced to mixed by applying/co-sputtering (e.g., the material A and the surfactant B may be mixed evenly (e.g., formed a homogeneous mixture) than the previous immiscible-mixing step 405). At the annealing step 415, the mixed material A and surfactant B may be heated and cooled slowly. Such heating and cooling process may cause the surface segregation between the material A and the surfactant B.

If (e.g., when) the annealing step 415 is performed at a temperature exceeding a threshold amount and for a period of time exceeding a threshold time (e.g., for the long-range diffusion) in response to bulk materials, a phase separation 420 may be observed. For example, the material A may be aggregated in bulk, and the A-B compound (e.g., an AₙBₘ compound formed from the enforced-mixing step 410) and the surfactant B may be aggregated in bulk, therefore, the phase separation 420 may be observed resulting from the aggregation of the material A and the aggregation of the A-B compound and the surfactant B.

If (e.g., when) the annealing step 415 is performed at a temperature below a threshold amount (e.g., for the short-range diffusion) in response to nanoscale materials, a surface separation 425 may be observed. For example, the material A may be aggregated (e.g., forming a smooth surface of a layer made of the material A), and the A-B compound (e.g., an AₙBₘ compound formed from the enforced-mixing step 410) and the surfactant B may be aggregated (e.g., forming a smooth surface of a layer made of the A-B compound and the surfactant B) during the annealing step 415, therefore, the surface separation 425 may be observed between the aggregation of the material A and the aggregation of the A-B compound and the surfactant B due to the immiscibility between the two layers. Because of the nature of surface segregation, the surfactant (e.g., the surfactant B) may readily be removed after depositing the layer (e.g., material A) in the deposition process.

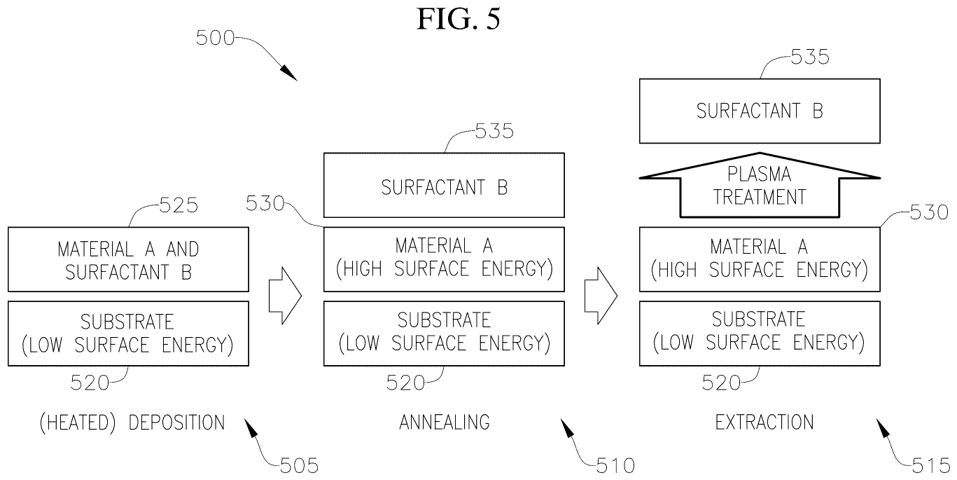

FIG. 5 is a diagram depicting an example method for forming a layer on a substrate, according to one or more embodiments. Although FIG. 5 illustrates various operations in a method for forming a layer on a substrate, embodiments according to the present disclosure are not limited thereto, and according to various embodiments, the method for forming a layer may include additional operations, or fewer operations, or the order of operations may vary, unless otherwise stated or implied, without departing from the spirit and scope of embodiments according to the present disclosure.

Referring to FIG. 5, a forming process 500 may include a deposition step 505, an annealing step 510, and an extraction step 515. At the deposition step 505, a mixture of material A and surfactant B 525 (e.g., the mixture of material A and surfactant B prepared utilizing the method (the immiscible step 405 and the enforced-mixing step 410) disclosed in FIG. 4) may be deposited on a substrate 520. In one or more embodiments, the substrate 520 may include an oxide selected from among MgO, SrO, BaO, CaO, and Mg—Al—Oₓ. The oxide(s) included in the substrate 520 may not be limited thereto, and according to various embodiments, the oxide(s) included in the substrate 520 may be any suitable oxides in the manufacturing process of the MRAM cells. For example, the forming process 500 may be for a MRAM device, in which a Fe-based free layer may be deposited (e.g., with the surfactant) onto an oxide-based substrates, as in the oxides may be functioned as a tunneling barrier that may provide some of the major MRAM properties, such as Perpendicular Magnetic Anisotropy (PMA) and/or Tunneling Magnetoresistance (TMR).

In one or more embodiments, the deposition step 505 may include applying/co-sputtering the mixture of material A and surfactant B 525 to deposit the mixture of material A and surfactant B 525 on the substrate 520. In one or more embodiments, the material A may be the main material for a free layer in the MRAM cell (e.g., a Fe-based layer). In one or more embodiments, the material A may include at least one component selected from among Fe-based compound (e.g., Fe, FeB, and/or CoFeB) and Heusler compounds (e.g., Mn₃Ge and/or MnAlGe).

In one or more embodiments, the surfactant B may be any materials that may be utilized/functioned as a surfactant (e.g., a Fe-based surfactant with low surface energy), and may include an element selected from among F, He, Ne, Ar, Kr, Xe, Na, K, Rb, Ba, Br, Bi, Te, Se, Pb, Tl, Li, Sr, As, Y, Ca, and Sb. For example, the surfactant B may be a surfactant including an element selected from among F, He, Ne, Ar, Kr, Xe, Na, K, Rb, Ba, Br, Bi, Te, Se, Pb, Tl, Li, Sr, As, Y, Ca, and Sb that may form a compound with Fe to lower the surface energy of the material A, such that the surfactant B that is to be mixed/blended with the material A (e.g., the material of the free layer in cells) may be beneficial to form a uniform, even layer of the material A on a substrate/a tunneling barrier by lowering the surface energy of the deposited layer (e.g., the layer of the material A). In one or more embodiments, the concentration of the surfactant B (e.g., the surfactant) in the mixture of the material A and the surfactant B may be in a range of about 1 mol % to about 25 mol % based on 100 mol % of the mixture of the material A and the surfactant B.

In one or more embodiments, the deposition step 505 may be a heated deposition, which may be beneficial to surface segregation. For example, the deposition step 505 may be performed at a temperature below a threshold, e.g., at a lower temperature for low-temperature annealing in response to the scale of annealing. For example, nanomaterial annealing may be a short-range diffusion (e.g., more localized and rapid) to prompt surface segregation, such that a lower temperature may be more suitable for such nanomaterial annealing. In one or more embodiments, the deposition step 505 may be performed at the temperature between about 150 °C and about 400 °C.

In one or more embodiments, the substrate 520 may have low surface energy. By applying/co-sputtering the surfactant (with low surface energy) with the deposition material (e.g., the material A) at early stages in the forming process 500 may create a smooth surface. For example, the deposition step 505 may be the first step of the forming process, by mixing the surfactant (e.g., the surfactant B) in the material A, the formation of the layer of the material A may be relatively smooth and even.

At the annealing step 510, the substrate 520 and the layer formed by the mixed material A and surfactant B 525 may be heated and cooled slowly, and a surface segregation may be observed. For example, a layer of the material A 530 may be formed and separated from a layer of the surfactant B 535 via the surface segregation. The annealing step 510 may be beneficial to the surface segregation. Because the annealing process may provide the energy and mobility for atoms to migrate and reach a stable state (e.g., the lowest energy state of an atom), thereby enhancing the surface segregation between the material A and the surfactant B because they each have their own energy state. Because the nature of the surface segregation can be promoted by immiscibility between the material A and the surfactant B (e.g., the surface segregation between two materials/substances may be enhanced if (e.g., when) the two materials/substances are naturally unable to mix or form homogeneity), the occurrence of surface segregation may improve the subsequent process of surfactant removal (e.g., the extraction step 515).

In one or more embodiments, the layer of the material A 530 may have high surface energy, and the layer of the surfactant B 535 may have low surface energy.

In one or more embodiments, the annealing step 510 may be performed at the temperature from about 150 °C to about 400 °C for a period of time from about 50 seconds to about 3 hours.

At the extraction step 515, an extraction treatment (e.g., a removal process for the surfactant) may be performed to remove the layer of the surfactant B 535 from the layer of the material A 530. In one or more embodiments, the extraction treatment may be a plasma treatment at the temperature between about 250 °C and about 400 °C. For example, the plasma treatment may remove the surfactant by utilizing energetic, reactive species, such as ions, electrons, and/or radicals, from a plasma to physically bombard and chemically break down the surfactant molecules into volatile compounds, e.g., carbon dioxide and/or carbon monoxide. Such volatile byproducts may then be removed from the surface of the layer of the material A 530, for example, via low vacuum, resulting in a clean, even surface for the layer of material A 530.

In one or more embodiments, the deposition step 505, the annealing step 510, and/or the extraction step 515 may be repeatedly perform to achieve a set thickness of the layer of the material A or a smooth surface of the material A if needed.

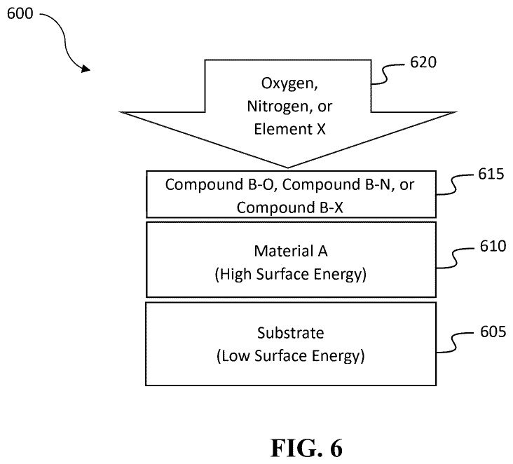

FIG. 6 is a diagram depicting an example extraction step, according to one or more embodiments. Although FIG. 6 illustrates various operations in an extraction operation, embodiments according to the present disclosure are not limited thereto, and according to various embodiments, the operation may include additional operations, or fewer operations, or the order of operations may vary, unless otherwise stated or implied, without departing from the spirit and scope of embodiments according to the present disclosure.

Referring to FIG. 6, an extraction step 600 (e.g., the extraction step 515 shown in FIG. 5) may be a process selected from among an oxidation with surfactant B, a nitridation with the surfactant B, and a formation of a surfactant B-element X compound 620 to from a layer 615 including the surfactant B to separate the surfactant B from material A 610 deposited on a substrate 605. In one or more embodiments, X may refer to any chemical elements other than Oxygen (O) and Nitrogen (N), e.g., an element that may react with the surfactant B (e.g., a surfactant) to form a stable compound (e.g., Compound B-X) to be separated/removed from the material A 610. For example, by forming an oxide of the surfactant B (e.g., Compound B—O; Oxide of B), a nitride of the surfactant B (e.g., Compound B—N; Nitride of B), and/or a B—X compound of the surfactant B (e.g., Compound B—X), the surfactant B may be removed from the material A. The formation of the oxide of the surfactant B, the nitride of the surfactant B, or the surfactant B-element X compound may neutralize the surfactant B (e.g., chemically break down the organic structure of the surfactant into smaller, non-reactive compounds), such that the neutralized surfactant B may be readily removed via a physical process, e.g., etching.

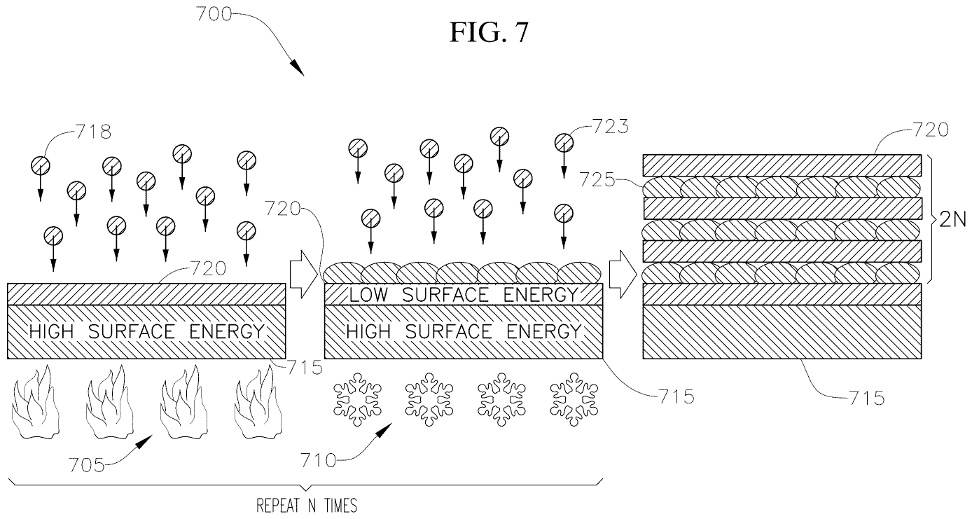

FIG. 7 is a diagram depicting example method for depositing multiple layers on a substrate, according to one or more embodiments. Although FIG. 7 illustrates various operations in a method for depositing multiple layers on a substrate, embodiments according to the present disclosure are not limited thereto, and according to various embodiments, the method may include additional operations, or fewer operations, or the order of operations may vary, unless otherwise stated or implied, without departing from the spirit and scope of embodiments according to the present disclosure.

Referring to FIG. 7, a method 700 may include a first deposition step 705 and a second deposition step 710. At the first deposition step 705, a first material 718 may be deposited on a substrate 715 to form a first layer 720. In one or more embodiments, the first material 718 may include Cobalt (Co) and may have lower surface energy than the material of the substrate 715. For example, the first layer 720 may have lower energy than the substrate 715. In one or more embodiments, the first deposition step 705 may be a heated deposition. For example, when depositing the materials having lower surface energy than a substrate/a previous layer having higher surface energy (e.g., depositing the first layer 720 on the substrate 715), the materials having lower surface energy may prefer/tend to evenly spread over the substrate, and a heated deposition may be helpful to deposit the materials having lower surface energy more evenly by accelerating diffusion.

At the second deposition step 710, a second material 723 may be deposited on the first layer 720 to form a second layer 725. In one or more embodiments, the second material 723 may include Iridium (Ir) and may have higher surface energy than the first material. For example, the second layer 725 may have higher surface energy than the first layer 720. In one or more embodiments, the second deposition step 710 may be a cooled deposition. For example, when depositing the materials having higher surface energy on a substrate/a previous layer having lower surface energy (e.g., depositing the second layer 725 on the first layer 720), the materials having higher surface energy may prefer/tend to create islands over the substrate/the previous layer, and the cooled deposition may be able to prevent or reduce the formation of islands by freezing diffusion (e.g., stopping diffusion). In one or more embodiments, a surfactant (e.g., the surfactant disclosed in FIGS. 2 to 6) may be added to the second material for depositing the second layer 725. For example, the surfactant (e.g., a Fe-immiscible surfactant having low surface energy) may be mixed with the second material to deposit the second layer 725 on the first layer 720 evenly and smoothly. The surfactant may later be removed or segregated by the approaches disclosed in FIGS. 5 and 6 (e.g., a plasma treatment and/or a formation of an oxide, a nitride, and/or a surfactant-X compound).

Furthermore, the first deposition step 705 and the second deposition step 710 may be alternatively and/or repeatedly performed to deposit the first layer 720 and the second layer 725 alternatively to achieve a set thickness. For example, the first deposition step 705 and the second deposition step 710 may be performed repeatedly for N times to form layers (e.g., the first layer 720 and the second layer 725) of a number of 2N on the substrate 715, in response to a set need of a stacked structure for a semiconductor device.

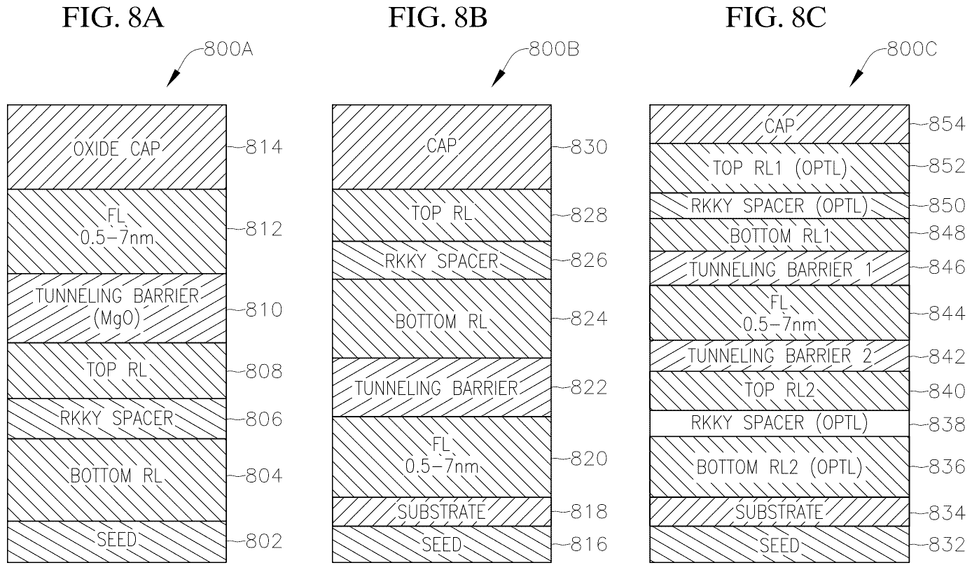

FIG. 8A is a diagram depicting an example MRAM cell, according to one or more embodiments. Although FIG. 8A illustrates various layers and materials in MRAM cells according to some embodiments, embodiments are not limited thereto, and according to various embodiments, an MRAM cell may include additional or fewer layers or materials, or the order of the layers or materials may vary, unless otherwise stated or implied, without departing from the spirit and scope of embodiments according to the present disclosure.

Referring to FIG. 8A, a first MRAM cell 800A may be formed utilizing the methods disclosed in FIGS. 4 to 7. The first MRAM cell 800A may include a seed layer 802, a bottom reference layer 804, an Ruderman-Kittel-Kasuya-Yosida (RKKY) spacer 806, a top reference layer 808, a tunneling barrier 810, a free layer 812, and an oxide cap 814. For example, the first MRAM cell 800A may be a memory component that may store binary data (e.g., 0s and 1s) by changing the orientation of its internal magnetic layer. The first MRAM cell 800A may include two ferromagnetic layers separated by a thin insulating layer, such as a fixed layer (e.g., the top reference layer 808) and a free layer (e.g., the free layer 812), separated by a thin insulating tunnel barrier (e.g., the tunneling barrier 810), forming a magnetic tunnel junction (MTJ). The seed layer 802 may be a thin foundational layer beneath the MTJ to provide smooth and uniform growth of the overlying layers (e.g., the bottom reference layer 804, the RKKY spacer 806, the top reference layer 808, the tunneling barrier 810, the free layer 812, and the oxide cap 814). The bottom reference layer 804 and the top reference layer 806 may be magnetic layers with a fixed magnetization serving as a spin polarizer for the free layer 812. The bottom reference layer 804 and the top reference layer 806 may be separated by the RKKY spacer 806, which may be a non-magnetic barrier or metallic layer that separates the bottom reference layer from the free layer 812, enabling the tunneling of spin-polarized electrons and defining the resistance of the first MRAM cell 800A. The oxide cap 814 may be a thin, insulating layer of metal oxide deposited/placed within or on top of the MTJ (e.g., on the free layer 812) to improve the thermal stability of the first MRAM cell 800A, reinforce magnetic properties of the first MRAM cell 800A, and/or prevent or reduce material interdiffusion of the first MRAM cell 800A.

In one or more embodiments, the tunneling barrier 810 may include MgO. If (e.g., when) the tunneling barrier 810 may have lower surface energy than the free layer 812, the methods disclosed in FIGS. 4 to 7 may be utilized to deposit the free layer 812 on the tunneling barrier 810. For example, the material of the free layer 812 may be mixed with a surfactant having lower surface energy during the deposition process to improve the formation of the free layer 812 on the tunneling barrier 810. The surfactant may then be removed via the methods disclosed in FIGS. 4 to 7, e.g., via an annealing process, an oxidation process, a nitridation process, a formation process of a surfactant-element X compound, and/or a plasma treatment.

In one or more embodiments, the thickness of the free layer 812 may be in a range of about 0.5 nm to about 7 nm.

FIG. 8B is a diagram depicting another example MRAM cell, according to one or more embodiments. Although FIG. 8B illustrates various layers and materials in MRAM cells according to some embodiments, embodiments are not limited thereto, and according to various embodiments, an MRAM cell may include additional or fewer layers or materials, or the order of the layers or materials may vary, unless otherwise stated or implied, without departing from the spirit and scope of embodiments according to the present disclosure.

Referring to FIG. 8B, a second MRAM cell 800B may be formed utilizing the methods disclosed in FIGS. 4 to 7. The second MRAM cell 800B may include a seed layer 816, a substrate 818, a free layer 820, a tunneling barrier 822, a bottom reference layer 824, an RKKY spacer 826, a top reference layer 828, and a cap 830.

In the embodiment disclosed in FIG. 8B, the second MRAM cell 800B may be a memory component that may be functionally similar to the first MRAM cell 800A disclosed in FIG. 8A but with a different stacked structure. For example, the seed layer 816 may be substantially the same or similar to the seed layer 802 disclosed in FIG. 8A, and the substrate 818 may be deposited on the seed layer 816. A MTJ on the substrate 818 of the second MRAM cell 800B may include the free layer 820 and the bottom reference layer 824, separated by the tunneling barrier 822, in which the free layer 820, the bottom reference layer 824, and the tunneling barrier 822 may be substantially the same or similar to the free layer 812, the bottom reference layer 804, and the tunneling barrier 810 disclosed in FIG. 8A. In this embodiment, a spin polarizer for the free layer 820 may be on the MTJ and include the top reference layer 828 and the bottom reference layer 824, separated by the RKKY spacer 826, in which the top reference layer 828, the bottom reference layer 824, and the RKKY spacer 826 may be substantially the same or similar to the top reference layer 808, the bottom reference layer 804, and the RKKY spacer 806 disclosed in FIG. 8A. The cap 830 may be an oxide cap (e.g., the oxide cap 814 disclosed in FIG. 8A) deposited/placed within or on top of the top reference layer 828 to improve the thermal stability of the second MRAM cell 800B, reinforce magnetic properties of the second MRAM cell 800B, and/or prevent or reduce material interdiffusion of the second MRAM cell 800B.

In one or more embodiments, the substrate 818 may include MgO. If (e.g., when) the substrate 818 may have lower surface energy than the free layer 820, the methods disclosed in FIGS. 4 to 7 may be utilized to deposit the free layer 820 on the substrate 818. For example, the material of the free layer 820 may be mixed with a surfactant having lower surface energy during the deposition process to improve the formation of the free layer 820 on the substrate 818. The surfactant may then be removed via the methods disclosed in FIGS. 4 to 7, e.g., via an annealing process, an oxidation process, a nitridation process, a formation process of a surfactant-element X compound, and/or a plasma treatment.

In one or more embodiments, the thickness of the free layer 820 may be in a range of about 0.5 nm to about 7 nm.

FIG. 8C is a diagram depicting yet another example MRAM cell, according to one or more embodiments. Although FIG. 8C illustrates various layers and materials in MRAM cells according to some embodiments, embodiments are not limited thereto, and according to various embodiments, an MRAM cell may include additional or fewer layers or materials, or the order of the layers or materials may vary, unless otherwise stated or implied, without departing from the spirit and scope of embodiments according to the present disclosure.

Referring to FIG. 8C, a third MRAM cell 800C may be formed utilizing the methods disclosed in FIGS. 4 to 7. The third MRAM cell 800C may include a seed layer 832, a substrate 834, a second bottom reference layer 836, a second RKKY spacer 838, a second top reference layer 840, a second tunneling barrier 842, a free layer 844, a first tunneling barrier 846, a first bottom reference layer 848, a first RKKY spacer 850, a first top reference layer 852, and a cap 854.

In the embodiment disclosed in FIG. 8C, the third MRAM cell 800C may be a memory component that may be functionally similar to the first MRAM cell 800A disclosed in FIG. 8A but with a different stacked structure. For example, the seed layer 832 may be substantially the same or similar to the seed layer 802 disclosed in FIG. 8A, and the substrate 834 may be deposited on the seed layer 832. In this embodiment, a first spin polarizer for the free layer 844 may be on the substrate 834 and include the second bottom reference layer 836 and the second top reference layer 840, separated by the second RKKY spacer 838, in which the second bottom reference layer 836, the second top reference layer 840, and the second RKKY spacer 838 may be substantially the same or similar to the top reference layer 808, the bottom reference layer 804, and the RKKY spacer 806 disclosed in FIG. 8A. Furthermore, a second spin polarizer for the free layer 844 may be on the MTJ of the third MRAM cell 800C and include the first bottom reference layer 848 and the first top reference layer 852, separated by the first RKKY spacer 850, in which the first bottom reference layer 848, the first top reference layer 852, and the first RKKY spacer 850 may be substantially the same or similar to the top reference layer 808, the bottom reference layer 804, and the RKKY spacer 806 disclosed in FIG. 8A. The MTJ of the third MRAM cell 800C may be between the two spin polarizers, and include a structure of the free layer 820 and the second top reference layer 840 separated by the second tunneling barrier 842 or a structure of the free layer 820 and the first bottom reference layer 846 separated by the first tunneling barrier 846. In one or more embodiments, the first and second bottom reference layers 848, 836, the free layer 844, the first, second tunneling barriers 846, 842, and the first, second top reference layers 852, 840 may be substantially the same or similar to the bottom reference layer 804, the free layer 812, the tunneling barrier 810, and the top reference layer 808 disclosed in FIG. 8A, respectively. The cap 854 may be an oxide cap (e.g., the oxide cap 814 disclosed in FIG. 8A) deposited/placed within or on top of the first top reference layer 852 to improve the thermal stability of the third MRAM cell 800C, reinforce magnetic properties of the third MRAM cell 800C, and/or prevent or reduce material interdiffusion of the third MRAM cell 800C.

In one or more embodiments, the second tunneling layer 842 may include MgO. If (e.g., when) the second tunneling layer 842 may have lower surface energy than the free layer 844, the methods disclosed in FIGS. 4 to 7 may be utilized to deposit the free layer 844 on the second tunneling layer 842. For example, the material of the free layer 844 may be mixed with a surfactant having lower surface energy first during the deposition process to improve the formation of the free layer 844 on the second tunneling layer 842. The surfactant may then be removed via the methods disclosed in FIGS. 4 to 7, e.g., via an annealing process, an oxidation process, a nitridation process, a formation process of a surfactant-element X compound, and/or a plasma treatment.

In one or more embodiments, the first top reference layer 852, the first RKKY spacer 850, the second bottom reference layer 836, and a second RKKY spacer 838 may be optional. In one or more embodiments, the thickness of the free layer 844 may be in a range of about 0.5 nm to about 7 nm.

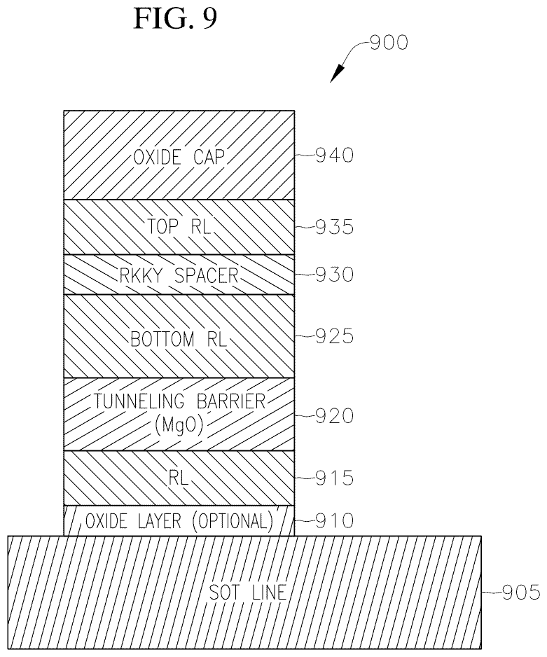

FIG. 9 is a diagram depicting an example Spin-Orbit Torque (SOT) MRAM cell, according to one or more embodiments. Although FIG. 9 illustrates various layers and materials in an SOT MRAM cell according to some embodiments, embodiments are not limited thereto, and according to various embodiments, a SOT MRAM cell may include additional or fewer layers or materials, or the order of the layers or materials may vary, unless otherwise stated or implied, without departing from the spirit and scope of embodiments according to the present disclosure.

Referring to FIG. 9, a SOT MRAM cell 900 may be formed utilizing the methods disclosed in FIGS. 4 to 7. The SOT MRAM cell 900 may include a SOT line 905, an oxide layer 910, a free layer 915, a tunneling barrier 920, a bottom reference layer 925, a RKKY spacer 930, a top reference layer 935, and an oxide cap 940. For example, the SOT line 905 of the SOT MRAM 900 may be a heavy metal path (e.g., tungsten) for a current that may generate a spin-orbit torque to switch the magnetization of the free layer 915. The SOT line 905 may separate the write and read paths, improving speed, efficiency, and endurance of the SOT MRAM 900, where the write current passes directly through an MTJ. The MTJ of the SOT MRAM 900 may be a component that may store data and include the free layer 915 and the bottom reference layer 925 (e.g., two ferromagnetic layers) separated by the tunneling barrier 920. A spin polarizer for the free layer 915 may be on the MTJ of the SOT MRAM 900 and include the bottom reference layer 925 and the top reference layer 935, separated by the RKKY spacer 930, in which the bottom reference layer 925, the top reference layer 935, and the RKKY spacer 925 may be substantially the same or similar to the top reference layer 808, the bottom reference layer 804, and the RKKY spacer 806 disclosed in FIG. 8A. In one or more embodiments, the oxide layer 910 may be a thin, non-magnetic insulator and include MgO. If (e.g., when) the oxide layer 910 may have lower surface energy than the free layer 915, the methods disclosed in FIGS. 4 to 7 may be utilized to deposit the free layer 915 on the oxide layer 910. For example, the material of the free layer 915 may be mixed with a surfactant having lower surface energy during the deposition process to improve the formation of the free layer 915 on the oxide layer 910. The surfactant may then be removed via the methods disclosed in FIGS. 4 to 7, e.g., via an annealing process, an oxidation process, a nitridation process, a formation process of a surfactant-element X compound, and/or a plasma treatment.

In one or more embodiments, the oxide layer 910 may be optional. In one or more embodiments, the tunneling barrier 920 may include MgO.

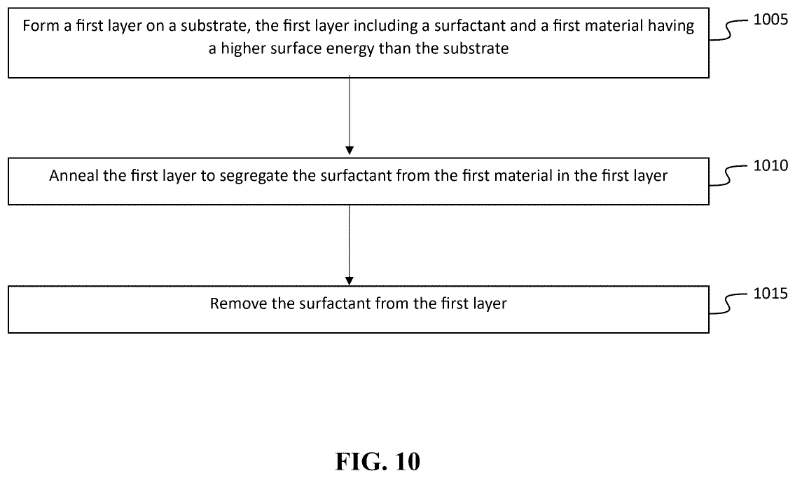

FIG. 10 is a flowchart depicting a method for depositing a layer on a substrate, according to some embodiments of the present disclosure. Although FIG. 10 illustrates various operations in a method for depositing a layer on a substrate, one or more embodiments according to the present disclosure are not limited thereto, and according to one or more embodiments, the method may include additional operations or fewer operations, or the order of operations may vary, unless otherwise stated or implied, without departing from the spirit and scope of embodiments according to the present disclosure.

Referring to FIG. 10, at operation 1005, an apparatus may form a first layer on a substrate. In one or more embodiments, the first layer may include a surfactant and a first material having a higher surface energy than the substrate. In one or more embodiments, the first material may have a higher surface energy than the surfactant, so that the difference of the surface energies between the first material and the surfactant may be beneficial to segregating the surfactant from the first material in the annealing process. In one or more embodiments, the forming of the first layer on the substrate may include applying/co-sputtering the first material and the surfactant on the substrate. In one or more embodiments, the forming of the first layer on the substrate may include applying/co-sputtering the first material and the surfactant on the substrate at a temperature from about 150 °C to about 400 °C. In one or more embodiments, the first material may include at least one of Fe, FeB, CoFeB, Mn₃Ge, or MnAlGe. In one or more embodiments, the surfactant may include at least one of F, He, Ne, Ar, Kr, Xe, Na, K, Rb, Ba, Br, Bi, Te, Se, Pb, Tl, Li, Sr, As, Y, Ca, or Sb. In one or more embodiments, the substrate may include at least one of MgO, SrO, BaO, CaO, or Mg—Al—Oₓ.

At operation 1010, the apparatus may anneal the first layer to segregate the surfactant from the first material in the first layer. In one or more embodiments, the annealing of the first layer may be performed for a period of time from about 50 seconds to about 3 hours at a temperature below a first threshold, for example, a temperature below about 400 °C. In one or more embodiments, the annealing of the first layer may be performed at a temperature between about 150 °C and about 400 °C.

At operation 1015, the apparatus may extract the surfactant from the first layer. In one or more embodiments, the surfactant may be extracted from the first layer via a plasma treatment at a temperature from about 250 °C to about 400 °C. In one or more embodiments, the surfactant may be extracted from the first layer via at least one process selected from among an oxidation, a nitridation, and a formation of a surfactant-element X compound. For example, the extraction of the surfactant may include forming an oxide of the surfactant, a nitride of the surfactant, and/or a miscibled compound of the surfactant (e.g., a surfactant-element X compound).

In one or more embodiments, the apparatus may be configured to further perform forming a second layer on the first layer, where the second layer may include a second material having a lower surface energy than the first material. For example, a multi-layered structure may be formed by alternatively depositing layers having different surface energies on the substrate (e.g., alternatively depositing the first layer and the second layer repeatedly). In one or more embodiments, the apparatus may repeatedly perform the operations 1005, 1010, and 1015 to increase the thickness of the first layer (e.g., the free layer) as needed.

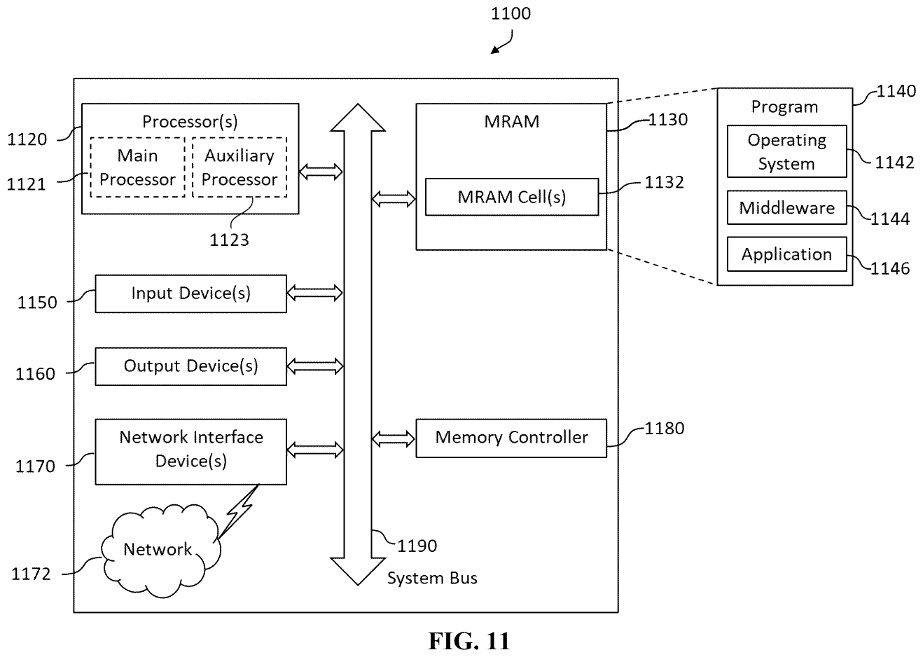

FIG. 11 is a block diagram of a system including a MRAM, according to one or more embodiments of the present disclosure.

Referring to FIG. 11, a system 1100 may include one or more processors 1120, a MRAM 1130, one or more input devices 1150, one or more output devices 1160, one or more network interface devices 1170, a memory controller 1180, and a system bus 1190. The processor 1120 may be coupled to the system bus 1190 and may intercouple other components (e.g., the MRAM 1130) included in the system 1100. As is well known, the processor 1120 may communicate with these other devices by exchanging address, control, and data information over the system bus 1190. Although not illustrated in FIG. 11, multiple system buses 1190 may be provided. Other devices may be connected to the system bus 1190. As illustrated in FIG. 11, these devices may include the MRAM 1130 and the input device 1150. The input device 1150 may include any type of input device, including but not limited to input keys, switches, voice processors, and/or the like. The other devices may also include the output device 1160, and the network interface device 1170. The output device 1160 may include any type of output device, including but not limited to audio, video, other visual indicators, and/or the like. In one or more embodiments, the system 1100 may be coupled to an external MRAM, which may include an operating system software, an application software or mobile application, and/or a user data area.

The network interface device 1170 may be configured to support one or more communications protocols to be used for the system 1100 to be coupled or connected to (e.g., exchange of data) an external electronic device (e.g., a server) or an external system directly (e.g., wired) or wirelessly (e.g., via a network 1172). The network interface device 1170 may be, for example, Ethernet ports, Wi-Fi adapters, cellular network interfaces, and/or loopback interfaces. The network 1172 may be any type of network, including but not limited to a wired or wireless network, a private or public network, a local area network (LAN), a wireless local area network (WLAN), a wide area network (WAN), a BLUETOOTH™ network, and/or the Internet.

The processor 1120 may execute software (e.g., a program 1140) to control at least one other component (e.g., a hardware or a software component) of the system 1100 coupled to the processor 1120, and may perform various data processing or computations. For example, the processor 1120 may execute instructions to perform methods disclosed in FIGS. 4 to 7, and 10 (e.g., depositing a layer on a substrate and/or producing a MRAM cell).

As at least a part of the data processing or computations, the processor 1120 may load a command or data received from another component (e.g., the input device 1150) in the MRAM 1130, may process the command or the data stored in the MRAM 1130, and may store resulting data in the MRAM 1130. The processor 1120 may include a main processor 1121 (e.g., a central processing unit or an application processor (AP)), and an auxiliary processor 1123 (e.g., a graphics processing unit (GPU), an image signal processor (ISP), a sensor hub processor, and/or a communication processor (CP)) that is operable independently from, or in conjunction with, the main processor 1121. Additionally or alternatively, the auxiliary processor 1123 may be adapted to consume less power than the main processor 1121, or to execute a particular function. The auxiliary processor 1123 may be implemented as being separate from, or a part of, the main processor 1121.

The auxiliary processor 1123 may control at least some of the functions or states related to at least one component (e.g., the input device 1150 and/or the output device 1160), as opposed to the main processor 1121 while the main processor 1121 is in an inactive (e.g., sleep) state, or together with the main processor 1121 while the main processor 1121 is in an active state (e.g., executing an application). The auxiliary processor 1123 (e.g., an image signal processor or a communication processor) may be implemented as part of another component (e.g., the input device 1150 and/or the output device 1160) functionally related to the auxiliary processor 1123.

The MRAM 1130 may include one or more MRAM cells 1132 that store various data used by at least one component (e.g., the processor 1120 and/or the input device 1150) of the system 1100. In one or more embodiments, the MRAM 1130 may be a non-volatile memory. The various data may include, for example, software (e.g., the program 1140) and input data or output data for a command related thereto. The program 1140 may be stored in the MRAM cell 1132 as software, and may include, for example, an operating system (OS) 1142, middleware 1144, and/or an application 1146. In one or more embodiments, the MRAM 1130 may be located in and reside on the same semiconductor as the system 1100. In one or more embodiments, the MRAM cell 1132 may be a MRAM cell shown in FIGS. 8A to 8C, and 9, which may be manufactured by the methods disclosed in FIGS. 4 to 7, and 10.

The memory controller 1180 may be utilized to manage communications with the MRAM 1130 via the system bus 1190. The memory controller 1180 may be configured to manage communication between the processor 1120 and the MRAM 1130, ensuring reliable data transfer and data storage.

The system bus 1190, which is coupled to the processor 1120, the memory controller 1180, and the MRAM 1130, may be a bus that is relatively wider in term of its bus width and is therefore relatively faster in data transfer rate as opposed to an external bus/interface component.

The input device 1150 may receive a command or data to be used by another component (e.g., the processor 1120) of the system 1100, from the outside (e.g., a user) of the system 1100. The input device 1150 may include, for example, a microphone, a mouse, and/or a keyboard.

Commands or data may be transmitted and/or received between the system 1100 and an external electronic device via the server coupled to the network 1172. All or some of operations to be executed at the system 1100 may be executed at one or more of the external electronic device and/or the server. The system 1100 may provide the outcome, with or without further processing of the outcome, as at least a part of a reply to the request. To that end, cloud computing, distributed computing, and/or client-server computing technology may be utilized, for example.

Embodiments of the subject matter and the operations described in this specification may be implemented in digital electronic circuitry, or in computer software, firmware, and/or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, and/or to control the operation of data-processing apparatus. Alternatively or additionally, the program instructions can be encoded on an artificially-generated propagated signal, e.g., a machine-generated electrical, optical, and/or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, and/or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices and/or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations may be depicted in the drawings in a particular order, this should not be understood as requiring that such operations be performed in the particular order shown or in any sequential order, or that all illustrated operations be performed, to achieve desirable results. In certain circumstances, multitasking and parallel processing may be advantageous or suitable. Moreover, the separation of various system components in the embodiments described above should not be understood as requiring such separation in all embodiments, and it should be understood that the described program components and systems can generally be integrated together in a single software product or packaged into multiple software products.

Thus, aspects of some embodiments of the present disclosure have been described herein. Other embodiments are within the scope of the following claims and their equivalents. In some cases, the actions set forth in the claims may be performed in a different order and still achieve desirable or desired results. Additionally, the processes depicted in the accompanying figures do not necessarily require the particular order shown, or sequential order, to achieve desirable or desired results. In certain implementations, multitasking and parallel processing may be advantageous, suitable or desirable.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims, with functional equivalents thereof to be included therein.

What is claimed is:

1. A method comprising:
forming a first layer on a substrate, the first layer comprising a surfactant and a first material having a higher surface energy than the substrate, wherein the forming of the first layer on the substrate comprises applying the first material and the surfactant on the substrate;
annealing the first layer to segregate the surfactant from the first material of the first layer; and
removing the surfactant from the first layer.

2. The method of claim 1, wherein the first material has a higher surface energy than the surfactant.

3. The method of claim 1, wherein the forming of the first layer on the substrate comprises co-sputtering the first material and the surfactant on the substrate under a temperature from 150 °C to 400 °C.

4. The method of claim 1, wherein the first material comprises at least one of Fe, FeB, CoFeB, Mn₃Ge, or MnAlGe.

5. The method of claim 1, wherein the surfactant comprises at least one of F, He, Ne, Ar, Kr, Xe, Na, K, Rb, Ba, Br, Bi, Te, Se, Pb, Tl, Li, Sr, As, Y, Ca, or Sb.

6. The method of claim 1, wherein the substrate comprises at least one of MgO, SrO, BaO, CaO, or Mg—Al—Oₓ.

7. The method of claim 1, wherein the annealing of the first layer is performed for a period of time from about 50 seconds to about 3 hours at a temperature from between about 150 °C and about 400 °C.

8. The method of claim 1, wherein the surfactant is removed from the first layer via a plasma treatment at a temperature from about 250 °C to about 400 °C.

9. The method of claim 1, wherein the surfactant is removed from the first layer via at least one process selected from among an oxidation, a nitridation, and a formation of a surfactant-element X compound.

10. The method of claim 1, further comprising forming a second layer on the first layer, wherein the second layer comprises a second material having a lower surface energy than the first material.

11. An apparatus comprising:
a processing circuit; and
a memory connected to the processing circuit,
the memory storing instructions that, when executed by the processing circuit, cause the receiver to perform a method, the method comprising:
forming a first layer on a substrate, the first layer comprising a surfactant and a first material having a higher surface energy than the substrate, wherein the forming of the first layer on the substrate comprises applying the first material and the surfactant on the substrate;
annealing the first layer to segregate the surfactant from the first material of the first layer; and
removing the surfactant from the first layer.

12. The apparatus of claim 11, wherein the first material has a higher surface energy than the surfactant.

13. The apparatus of claim 11, wherein the forming of the first layer further comprises applying the first material and the surfactant on the substrate at a temperature from about 150 °C to about 400 °C.

14. The apparatus of claim 11, wherein the first material comprises at least one of Fe, FeB, CoFeB, Mn₃Ge, or MnAlGe.

15. The apparatus of claim 11, wherein the surfactant comprises at least one of F, He, Ne, Ar, Kr, Xe, Na, K, Rb, Ba, Br, Bi, Te, Se, Pb, Tl, Li, Sr, As, Y, Ca, or Sb.

16. A system comprising an apparatus:
the apparatus comprising:
a processing circuit; and
a memory connected to the processing circuit,
the memory storing instructions that, when executed by the processing circuit, cause the receiver to perform a method, the method comprising: forming a first layer on a substrate, the first layer comprising a surfactant and a first material having a higher surface energy than the substrate;
annealing the first layer to segregate the surfactant from the first material of the first layer; and
removing the surfactant from the first layer.

17. The system of claim 16, wherein the forming of the first layer on the substrate comprises applying the first material and the surfactant on the substrate.

18. The system of claim 16, wherein the forming of the first layer on the substrate comprises applying the first material and the surfactant on the substrate at a temperature from about 150 °C to about 400 °C.

19. The system of claim 16, wherein the first material comprises at least one of Fe, FeB, CoFeB, Mn₃Ge, or MnAlGe.

20. The system of claim 16, wherein the surfactant comprises at least one of F, He, Ne, Ar, Kr, Xe, Na, K, Rb, Ba, Br, Bi, Te, Se, Pb, Tl, Li, Sr, As, Y, Ca, or Sb.
